(19) United States
(12) Patent Application Publication
(10) Pub. No.: US 2016/0163607 A1
(43) Pub. Date: Jun. 9, 2016

(54) SEMICONDUCTOR DEVICE, SEMICONDUCTOR SYSTEM AND METHOD OF TESTING SEMICONDUCTOR DEVICE

(71) Applicant: SK hynix Inc., Gyeonggi-do (KR)

(72) Inventors: Sang-Mook OH, Gyeonggi-do (KR); Jin-Hee CHO, Gyeonggi-do (KR)

(21) Appl. No.: 14/715,273

(22) Filed: May 18, 2015

(30) Foreign Application Priority Data
Dec. 5, 2014 (KR) 10-2014-0174019

(51) Int. Cl. H01L 21/66; G01R 31/12; G01R 31/26

(52) U.S. Cl. CPC H01L 22/32; G01R 31/2644; G01R 31/12

(57) ABSTRACT

A semiconductor device may include a semiconductor substrate doped with a first type impurity; a through electrode inserted in the semiconductor substrate; an active area formed in the semiconductor substrate to surround an upper portion of sidewalls of the through electrode, and doped with a second type impurity; an insulating layer formed between the semiconductor substrate and the through electrode, and between the active area and the through electrode; a drive circuit suitable for applying a first voltage to the through electrode in a test operation; and a test pad connected to the active area electrically in the test operation, to which a voltage is applied from outside.

### CROSS-REFERENCE TO RELATED APPLICATIONS

The present application claims priority of Korean Patent Application No. 10-2014-0174019, filed on Dec. 5, 2014, which is incorporated herein by reference in its entirety.

### BACKGROUND

1. Field

Exemplary embodiments of the present disclosure relate to a semiconductor device, a semiconductor system and a method of testing a semiconductor device.

2. Description of the Related Art

Semiconductor systems with high performance and high memory capacity are in need, and semiconductor devices are continuously scaled down for greater integration. This increased degree of integration has been achieved by, for example, reducing the channel length of MOSFETs and reducing the size of contacts for electrical interconnections. However, these approaches may cause malfunctions due to short channel effects and difficulties in wiring due to shrinking contact size. As these approaches reach their limit, novel alternatives are needed for increasing integration.

One such alternative, a three-dimensional (3D) semiconductor package, is actively being researched. This technology involves multiple stacked semiconductor devices, allowing for an increase in integration without increasing the horizontal surface area of the product. Through substrate/silicon vias (TSV) are often used in stacked semiconductor devices. A TSV is a conductor that provides an electrical connection through the stacked semiconductor devices.

FIG. 1 is a cross sectional view illustrating a semiconductor device in which a TSV is formed.

Referring to FIG. 1, the TSV 102 may be formed such that a TSV is inserted in a semiconductor substrate 101 included in the semiconductor device. Alternatively, the TSV 102 may be formed such that a TSV penetrates the semiconductor substrate 101. In addition, an insulating layer 103 may be formed between the semiconductor substrate 101 and the TSV 102.

A method of forming the TSV 102 in the semiconductor substrate 101 is as follows.

First, the semiconductor substrate 101 which is doped with P-type impurities is prepared. A via hole is formed from one side of the semiconductor substrate 101 to a direction perpendicular to a major axis of the semiconductor substrate 101. Next, the insulating layer 103 is formed along an inner wall of the semiconductor substrate 101, exposed by the via hole. Finally, a conductive material, for example, copper, is filled in the via hole and thus the TSV 102 is formed.

However, when the insulating layer 103 is formed, a crack 104 may be generated in the insulating layer 103. If the crack 104 exists in the insulating layer 103, the conductive material may leak while the conductive material is filled in the via hole. As a result, the semiconductor device may malfunction. In addition, it is difficult to proceed to subsequent processes after the conductive material is filled in the via hole, or a test device for testing the semiconductor device may be contaminated due to the leaked conductive material.

### SUMMARY

Various embodiments are directed to a semiconductor device, a semiconductor system and a method of testing a semiconductor device, capable of detecting whether a crack is present in an insulating layer surrounding a through electrode.

In an embodiment, a semiconductor device may include: a semiconductor substrate doped with a first type impurity; a through electrode inserted in the semiconductor substrate; an active area formed in the semiconductor substrate to surround an upper portion of sidewalls of the through electrode, and doped with a second type impurity; an insulating layer formed between the semiconductor substrate and the through electrode, and between the active area and the through electrode; a drive circuit suitable for applying a first voltage to the through electrode in a test operation; and a test pad connected to the active area electrically in the test operation, to which a voltage is applied from outside.

In an embodiment, a semiconductor device may include: a semiconductor substrate doped with a first type impurity; a plurality of through electrodes inserted in the semiconductor substrate; a plurality of active areas formed in the semiconductor substrate, each surrounding an upper portion of sidewalls of the respective through electrodes, doped with a second type impurity; a plurality of insulating layers, each formed between the semiconductor substrate and the respective through electrodes, and between the semiconductor substrate and the respective active areas; one or more signal receiving circuits suitable for receiving a signal transmitted through a corresponding one of the plurality of through electrodes; one or more signal transmitting and receiving circuits suitable for receiving a signal transmitted through a corresponding one of the plurality of through electrodes and transmitting a signal to be outputted to outside through the corresponding through electrode; and a plurality of test pads electrically connected to the plurality of active areas in a test operation, to which a voltage is applied from the outside, wherein the one or more signal receiving circuits and the one or more signal transmitting and receiving circuits apply a first voltage to the respective through electrodes in the test operation.

In an embodiment, a semiconductor system may include: a semiconductor device comprising; a semiconductor substrate doped with a first type impurity, a through electrode inserted in the semiconductor substrate, an active area formed in the semiconductor substrate to surround an upper portion of sidewalls of the through electrode, and doped with a second type impurity, an insulating layer formed between the semiconductor substrate and the through electrode, and between the semiconductor substrate and the active area, and a test pad connected to the active area electrically in a test operation, wherein a first voltage is applied to the through electrode in the test operation; and a test device suitable for applying a second voltage to the test pad in the test operation, and detecting whether a crack exists in the insulating layer by using current outputted through the test pad.

In an embodiment, a method of testing a semiconductor device may include: providing a semiconductor substrate doped with a first type impurity; forming an active area by doping a second type impurity in the semiconductor substrate; forming a via hole by penetrating the active area and etching the semiconductor substrate from one side of the semiconductor substrate to a direction perpendicular to a major axis of the semiconductor substrate; forming an insulating layer along an inner wall of the semiconductor substrate, the inner wall being exposed by the via hole; forming a through electrode over the insulating layer to fill the via hole; applying a first voltage to the through electrode and a second voltage to the active area; and detecting current flowing between the through electrode and the active area.

The present disclosure may form an active area surrounding an upper portion of sidewalls of a through electrode and an insulating layer included in a semiconductor device, apply first and second voltages to the through electrode and the active area, respectively, measure a current flowing between the through electrode and the active area, and therefore detect whether a crack is present in the Insulating layer.

### BRIEF DESCRIPTION OF THE DRAWINGS

FIG. 1 is a cross sectional view illustrating a semiconductor device in which a TSV is formed.

FIGS. 2A and 2B are diagrams illustrating a semiconductor device according to an embodiment.

FIG. 3 is a graph showing a change in an amount of a current I_{OUT} outputted to a test pad according to a change in a voltage difference between a through electrode and an active area.

FIGS. 4A to 4D are diagrams illustrating how current flows when a crack is present in an insulating layer of the semiconductor device shown in FIGS. 2A and 2B.

FIG. 5 is a diagram illustrating a semiconductor device according to an embodiment.

FIG. 6 is a diagram illustrating a semiconductor system according to an embodiment.

FIG. 7 is a flowchart illustrating a method of testing a semiconductor device according to an embodiment.

FIGS. 8A to 8F are cross sectional views illustrating the method of FIG. 7.

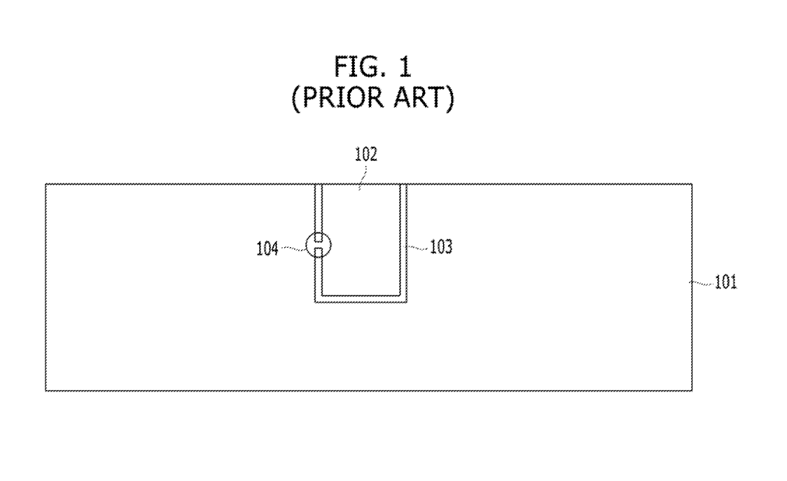

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated to clearly illustrate features of the embodiments. When a first layer is referred to as being “on” a second layer or “on” a substrate, it not only refers to where the first layer is formed directly on the second layer or the substrate but also to where a third layer exists between the first layer and the second layer or the substrate.

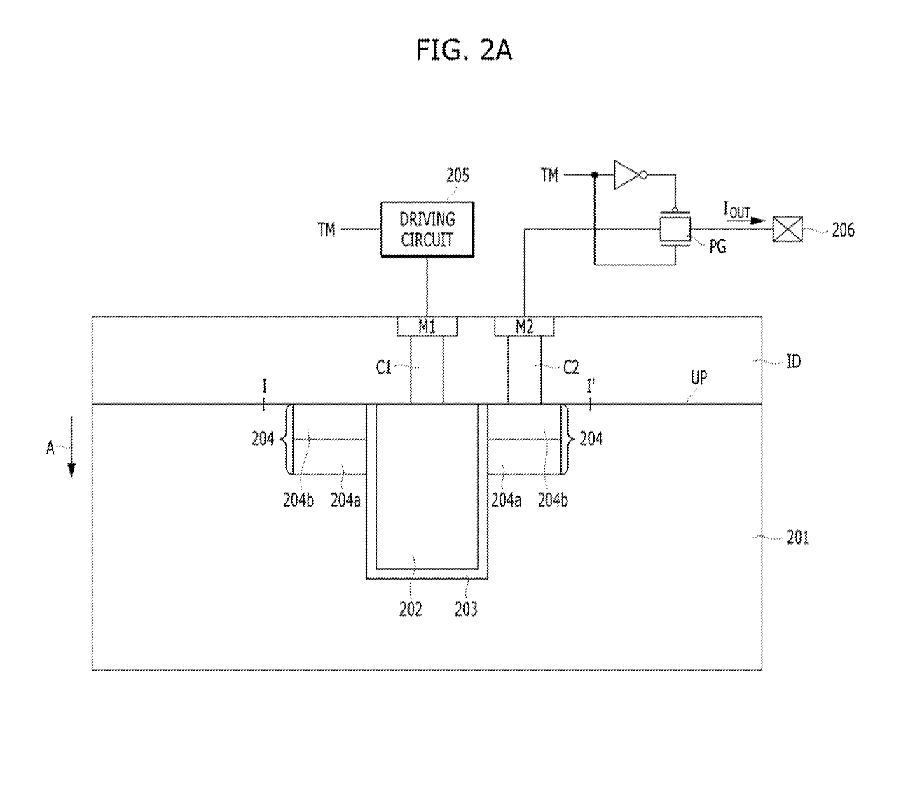

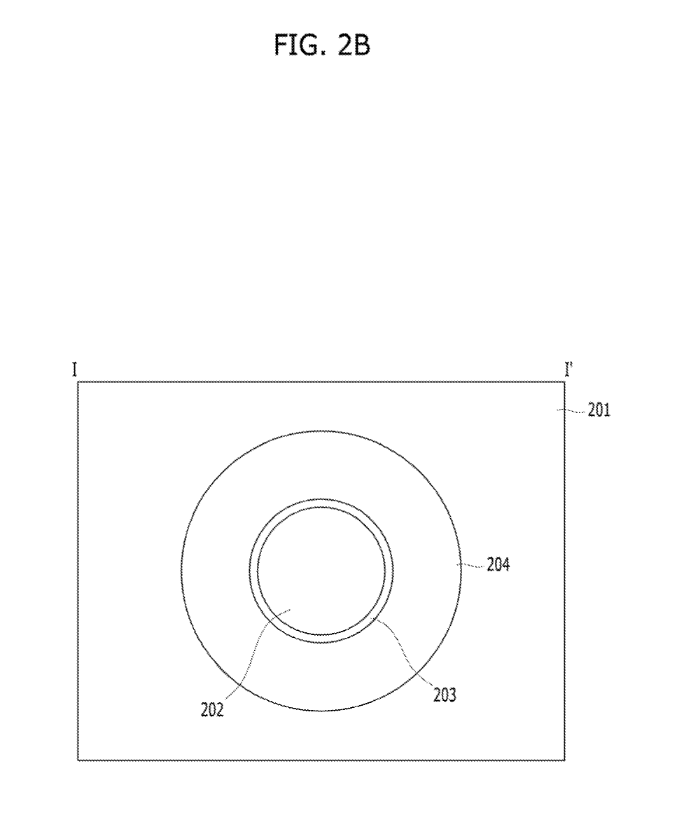

FIGS. 2A and 2B diagrams illustrating a semiconductor device according to an embodiment.

FIG. 2A shows a cross sectional view depicting a neighboring structure of a through electrode and a circuit diagram depicting a structure needed for testing the above structure. FIG. 2B is a plan view showing a first side UP of a semiconductor substrate 201 taken according to a line I-I′ of FIG. 2A.

Referring to FIG. 2A, the semiconductor device may include the semiconductor substrate 201, a through electrode 202, an insulating layer 203, an active area 204, a driving circuit 205 and a test pad 206.

The semiconductor substrate 201 may be a semiconductor layer which is formed on a base structure such as silicon, silicon-on-insulator (SOI) and silicon-on-sapphire (SOS) or a different base structure such as a lattice transformed semiconductor layer, or a hybrid substrate in which different substrates are bonded. The semiconductor substrate 201 is not limited to a silicon-based material, but may include Si—Ge, Ge; a III-V group semiconductor material such as Ga—As compound; a II-VI group semiconductor material such as ZnS, ZnSe, and CdSe; an oxide semiconductor material such as ZnO, MgO, MO₂; a nano scale material such as a carbon nano crystal; or a hybrid material thereof.

The semiconductor substrate 201 may be doped with a first type impurity. The first type impurity may be a P-type or an N-type impurity. The following assumes that the first type impurity is a P-type impurity, that is, the semiconductor substrate 201 is doped with the P-type impurity.

The through electrode 202 may have a structure inserted from the first side UP of the semiconductor substrate 201 to a direction A perpendicular to a major axis of the semiconductor substrate 201. The through electrode 202 may include a doped polysilicon; tungsten, aluminum, copper, gold, silver, tantalum, titanium, molybdenum, cobalt, nickel, platinum and palladium; an alloy thereof; a conductive nitride thereof; a conductive metal oxide thereof, or a silicon alloy thereof. However, these are examples and other conductive material, for example, a carbon electrode or other conductive material which may reduce a threshold voltage may be included.

Referring to FIG. 2B, the through electrode 202 may have a round shape when seen from a cross sectional view parallel to the first side UP of the semiconductor substrate 201. However, this is an example. For using a change of a threshold voltage according to a change of a trap concentration due to a crystalline direction of an opposing surface of an adjacent semiconductor substrate, the through electrode 202 may have an eclipse shape, a square shape, a diamond shape or a rhomboid shape, a hexagonal shape, other polygon shapes, a curve shape, or a combination thereof in a cross sectional view that is parallel to the first side UP of the semiconductor substrate 201.

The active area 204 may be formed in the semiconductor substrate 201 to surround an upper portion of sidewalls of the through electrode 202, and doped with a second type impurity. The second type impurity may be opposite to the first type impurity. The second type impurity may be an N-type or a P-type impurity. The following describes that the second type impurity is the N-type impurity, that is, the active area 204 is doped with the N-type impurity.

The insulating layer 203 may be formed between the through electrode 202 and the semiconductor substrate 201, and between the through electrode 202 and the active area 204. The insulating layer 203 may electrically isolate the through electrode 202 from the semiconductor substrate 201 and the active area 204. The insulating layer 203 may include a silicon oxide layer. In addition, the insulating layer 203 may include a high dielectric film including a silicon nitride film such as Si₃N₄; or a metal oxide film such as Al₂O₃, Ta₂O₅, HfO₂, ZrO₂, TiO₂, Y₂O₃, La₂O₃, (Ba, Sr)TiO₃, SrTiO₃, PbTiO₃, (Hf, Zr)O₂, Pu(Zr, Ti)O₃, BaTiO₃, SrBi₂2Ta₂O₉, KₓWO₃, or Bi₄4Ti₃O₁₂.

Referring to FIG. 2A, the active area 204 may contact an upper portion of sidewalls of the insulating layer 203 and a lower portion of the sidewalls of the insulating layer 203 may be exposed. As shown in FIG. 2B, the active area 204 may have a structure surrounding the upper portion of the sidewalls of the insulating layer 203. The active area 204 may include an N− well region 204a doped in a relatively low concentration and an N+ region 204b doped in a relatively high concentration.

The through electrode 202 and the active area 204 may be connected to metal wirings M1 and M2 through contacts C1 and C2, respectively. The metal wirings M1 and M2 may be connected to the driving circuit 205 and the test pad 206, respectively. That is, the through electrode 202 and the active area 204 may be electrically connected to the driving circuit 205 and the test pad 206 through the contacts C1 and C2 and metal wirings M1 and M2, respectively. Between the metal wirings M1 and M2 and the semiconductor substrate 201, an inter-layer insulating film ID may be formed for isolation, except an interconnection by the contacts C1 and C2. The inter-layer insulating film ID may be formed by BPSG (BoroPhospho Silicate Glass), PSG (Phospho Silicate Glass), FSG (Fluorinated Silicate Glass), HDP (High Density Plasma), TEOS (Tetra Ethyle Ortho Silicate), etc.

The driving circuit 205 may be connected to the through electrode 202 through the metal wiring M1, and may apply a first voltage to the through electrode 202 in a test operation. The first voltage may be a power supply voltage or a source voltage lower than the power supply voltage. The first voltage may be a power supply voltage. The driving circuit 205 may output the power supply voltage when a test mode signal TM is enabled.

The test pad 206 may be a pad to which a voltage is applied from outside (e.g. from an external device or test device) of the semiconductor device and through which a current is outputted to the outside of the semiconductor device. The test pad 206 may be connected to the metal wiring M2 through a pass gate PG which is turned on in the test operation. When the test mode signal TM is enabled, the pass gate PG is turned on and the test pad 206 may be connected electrically to the active area 204 through the metal wiring M2. In the test operation, a second voltage may be applied to the test pad 206. The second voltage may be the source voltage or the power supply voltage. The second voltage may be a source voltage.

In the test operation, when the power supply voltage is applied to the through electrode 202 and the source voltage is applied to the active area 204, a voltage difference is generated between the through electrode 202 and the active area 204. If a crack exists in the insulating layer 203, a current flows between the through electrode 202 and the active area 204. If a crack does not exist in the insulating layer 203, a current does not flow between the through electrode 202 and the active area 204. The current flowing between the through electrode 202 and the active area 204 may be outputted through the test pad 206 to the outside of the semiconductor device.

Therefore, it may be detected whether a crack exists in the insulating layer 203 by comparing amounts of current I_{OUT} outputted through the test pad 206 with a reference current having a predetermined value. If the current lour outputted through the test pad 206 is greater than or equal to the reference current, a crack may be present in the insulating layer 203. If the current I_{OUT} is smaller than the reference current, a crack may not be present in the insulating layer 203.

In the semiconductor device in FIG. 2, it may be detected whether a crack is present in the insulating layer 203 by forming the active area 204 surrounding the upper portion of the sidewalls of the through electrode 202, applying two different voltages respectively to the through electrode 202 and the active area 204 in the test operation, and detecting the current flowing therebetween.

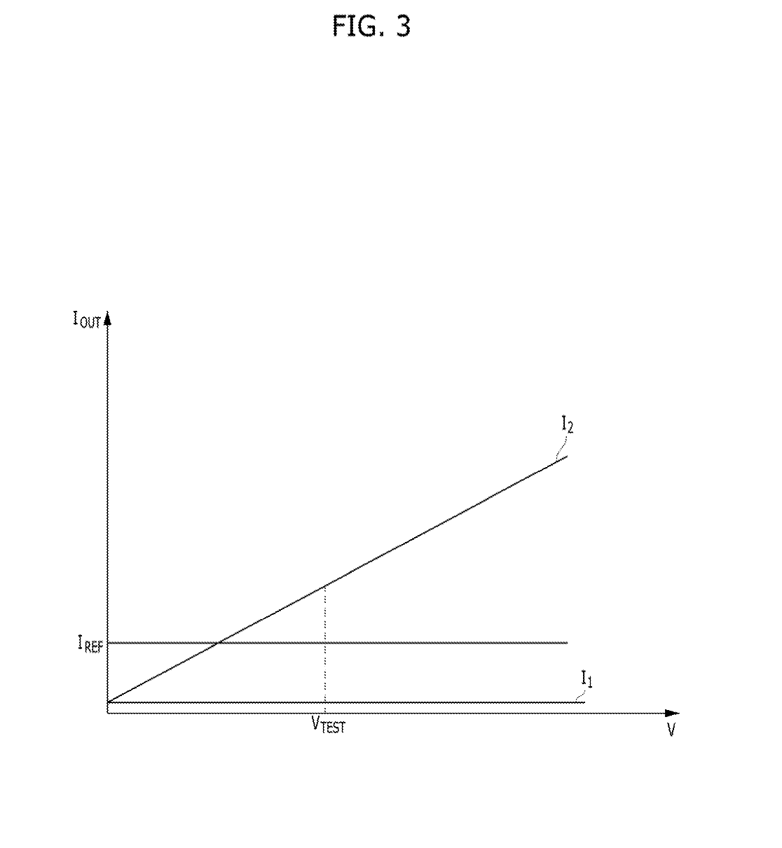

FIG. 3 is a graph showing a change in the amount of the current I_{OUT} outputted to the test pad 206 according to a change in a voltage difference V between the through electrode 202 and the active area 204.

In FIG. 3, a horizontal axis shows the voltage difference V between the through electrode 202 and the active area 204, and a vertical axis shows the amount of the output current I_{OUT}. The reference numeral ‘It’ shows the change of the amount of the output current I_{OUT} according to the change of the voltage difference V when a crack is not present in the insulating layer 203, and the reference numeral ‘I₂’ shows the change of the amount of the output current lour according to the change of the voltage difference V when a crack is present in the insulating layer 203.

Referring to FIG. 3, if a crack is not present in the insulating layer 203, the amount of the output current I_{OUT} is a small value near to zero regardless of the voltage difference V. If a crack is present in the insulating layer 203, the amount of the output current I_{OUT} increases as the voltage difference V increases. Therefore, a crack in the insulating layer 203 may be detected by determining the reference current I_{REF}, determining the voltage difference V to a value V_{TEST} such that ‘I₂’ is greater than or equal to the reference current I_{REF}, and by comparing the amount of the output current I_{OUT} with the reference current I_{REF}.

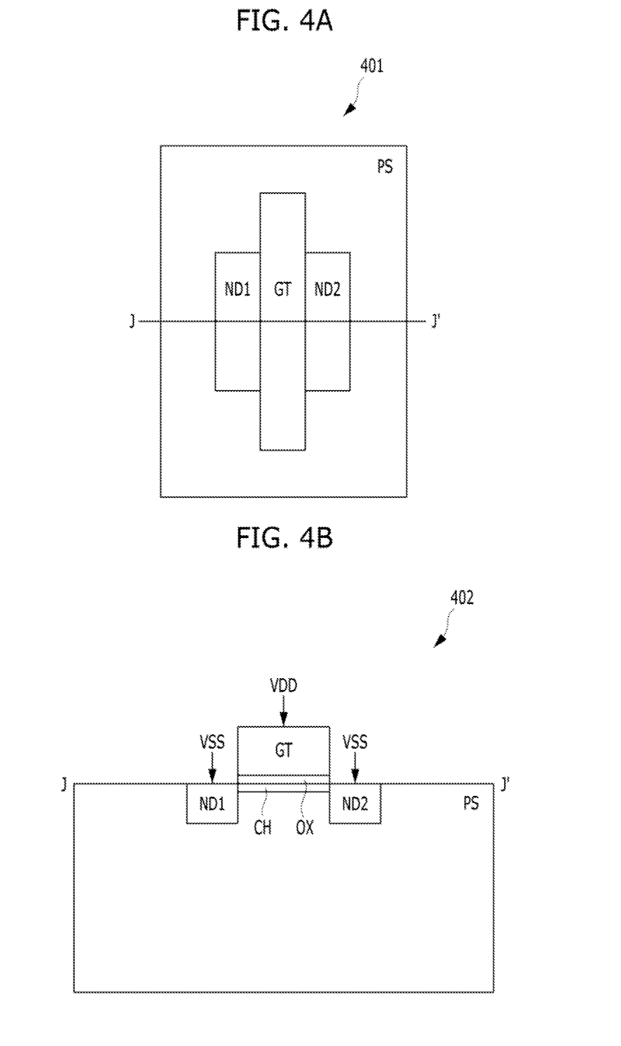

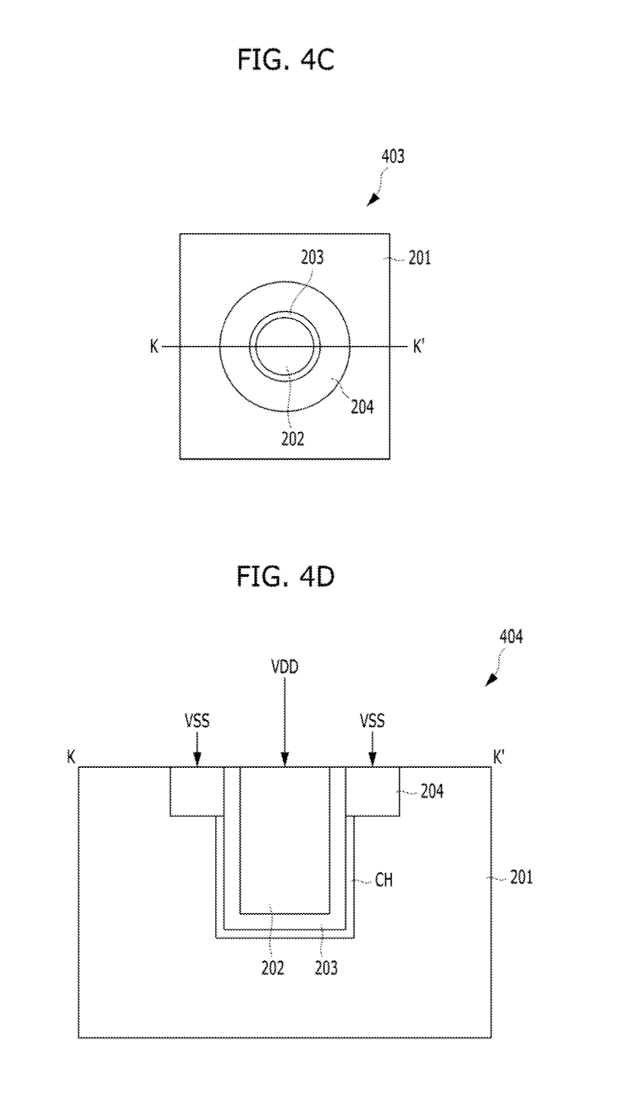

FIGS. 4A to 4D are diagrams illustrating how a current flows when a crack is present in the insulating layer 203 of the semiconductor device shown in FIGS. 2A and 2B.

FIG. 4A shows a plan view 401 of an NMOS transistor and FIG. 4B shows a cross sectional view 402 taken according to a line 3-3′ of FIG. 4A.

Referring to FIGS. 4A and 4B, the NMOS transistor may include a semiconductor substrate PS having a P-type impurity, active areas ND1 and ND2 wherein an N-type impurity is doped in the semiconductor substrate PS, an insulating layer OX and a gate GT. One of the active areas ND1 and ND2 may be a source, and the other may be a drain.

When a power supply voltage VDD is applied to the gate GT and a source voltage VSS is applied to the active areas ND1 and ND2, a channel CH is formed, which serves as a path for a current flowing in the semiconductor substrate PS adjacent to the insulating film OX. There is no voltage difference between the active areas ND1 and ND2 and therefore a current does not flow if a crack is not present in the insulating layer OX. However, if a crack is present in the insulating layer OX, a current flows through the channel CH due to a voltage difference between the gate GT and the active areas ND1 and ND2.

FIG. 4C shows a plan view 403 of the semiconductor device of FIG. 2B, and FIG. 4D shows a cross sectional view 404 taken according to a line K-K′ of FIG. 4C. In FIGS. 2A and 2B, and FIGS. 4C and 4D, the same reference numerals or the same reference designators denote the same elements.

Referring to FIGS. 4C and 4D, a semiconductor substrate 201 may correspond to the semiconductor substrate PS of the NMOS transistor of FIGS. 4A and 4B; a through electrode 202 may correspond to the gate GT of the NMOS transistor of FIGS. 4A and 4B; an insulating layer 203 may correspond to the insulating layer OX of the NMOS transistor of FIGS. 4A and 4B; and an active area 204 may correspond to the active areas ND1 and ND2 of the NMOS transistor of FIGS. 4A and 4B.

Similarly, as described regarding FIGS. 4A and 4B, the power supply voltage VDD is applied to the through electrode 202, the source voltage VSS is applied to the active area 204, and a channel CH is formed to surround the insulating layer 203 between the insulating layer 203 and the semiconductor substrate 201. If a crack is not present in the insulating layer 203, a current does not flow through the channel CH. If a crack is present in the insulating layer 203, a current flows through the channel CH due to a voltage difference between the through electrode 202 and the active area 204.

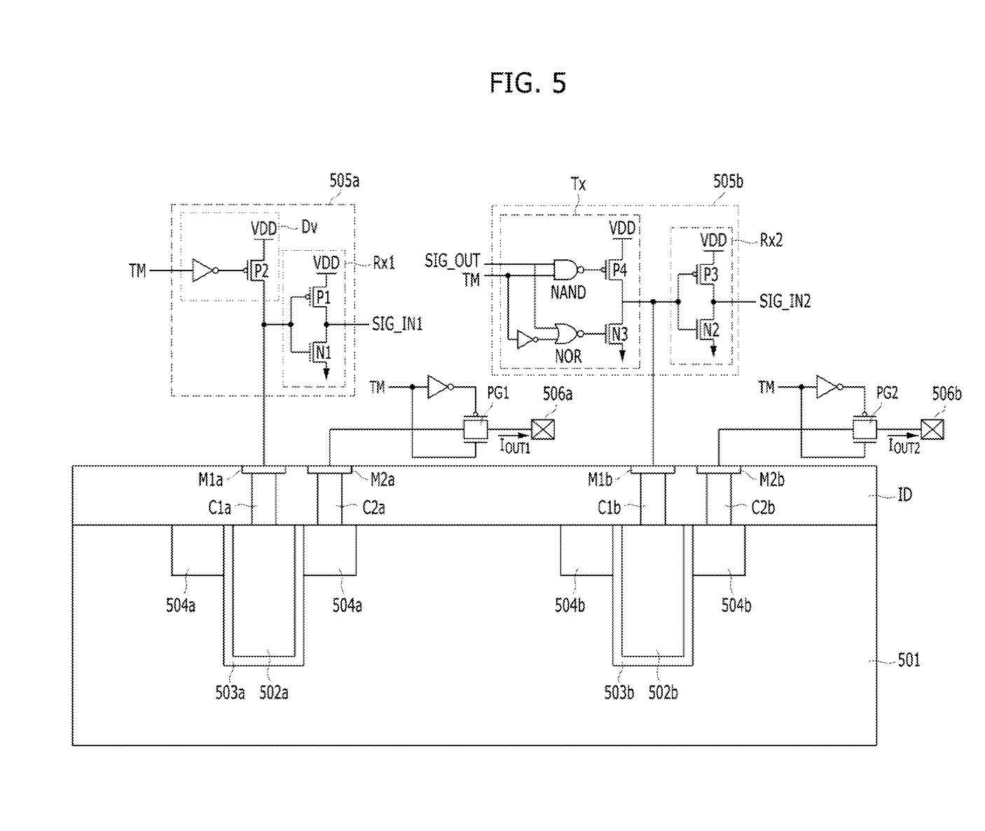

FIG. 5 is a diagram illustrating a semiconductor device according to an embodiment.

FIG. 5 shows a cross sectional view depicting a structure neighboring to a through electrode and a circuit diagram depicting a structure needed to test. In FIG. 5, a plan view of each through electrode is similar to that of FIG. 2B.

Referring to FIG. 5, the semiconductor device may include a semiconductor substrate 501, a first and a second through electrodes 502a and 502b, a first and a second active areas 504a and 504b, a signal receiving circuit 505a connected to the first through electrode 502a, a signal transmitting and receiving circuit 505b connected to the second through electrode 502b, and a first and a second test pads 506a and 506b.

The descriptions of the first and second through electrodes 502a and 502b and neighboring structures 503a, 503b, 504a, and 504b are the same as those of the through electrode 202 and a neighboring structure 203 and 204 in FIGS. 2A and 2B.

The signal receiving circuit 505a may receive a signal transmitted from outside of the semiconductor device through the first through electrode 502a. Referring to FIG. 5, the signal receiving circuit 505a may include a receiving part Rx1 for receiving the signal transmitted through the first through electrode 502a to output a first input signal SIG_IN1, and a driving part Dv for applying a power supply voltage VDD to the first through electrode 502a in a test operation.

The receiving part Rx1 may include transistors P1 and N1. The driving part Dv may include a transistor P2 which is turned on when the test mode signal TM is enabled in the test operation.

The signal transmitting and receiving circuit 505b may receive a signal transmitted from the outside of the semiconductor device through the second through electrode 502b; or may transmit an output signal SIG_OUT to be outputted to the outside of the semiconductor device through the second through electrode 502b. Referring to FIG. 5, the signal transmitting and receiving circuit 505b may include a receiving part Rx2 for receiving the signal transmitted through the second through electrode 502b to output a second output signal SIG_IN2, and a transmission part Tx for transmitting the output signal SIG_OUT to be outputted to the outside of the semiconductor device through the second through electrode 502b. In addition, the transmitting part Tx may apply the power supply voltage VDD to the second through electrode 502b in the test operation.

The receiving part Rx2 may include transistors P3 and N2. The transmitting part Tx may include gates NAND and NOR and transistors P4 and N3. The transmitting part Tx may drive the second through electrode 502b to a voltage determined in response to a logical value of the output signal SIG_OUT which is outputted when the test mode signal TM is disabled. The transmitting part Tx may apply the power supply voltage VDD to the second through electrode 502b when the test mode signal TM is enabled.

The first and second test pads 506a and 506b may be connected to the first and second active areas 504a and 504b, respectively, and may accomplish the same function as the test pad 206 in FIGS. 2A and 2B. In addition, contacts C1a, C2a, C1b and C2b, metal wirings M1a, M2a, M1b and M2b, an Inter-layer insulating film ID, and pass gates PG1 and PG2 may have the same function as the corresponding elements in FIGS. 2A and 2B.

The semiconductor device in FIG. 5 may detect whether a crack is present in each of the first and second insulating layers 503a and 503b by using currents I_{OUT1} and I_{OUT2} outputted to the first and second test pads 506a and 506b in the test operation.

The semiconductor device in FIG. 5 may be a semiconductor memory device for storing data. The signal receiving circuit 505a may receive command signals or address signals inputted to the semiconductor device. The signal transmitting and receiving circuit 505b may transmit and receive data inputted to the semiconductor memory device or outputted from the semiconductor memory device.

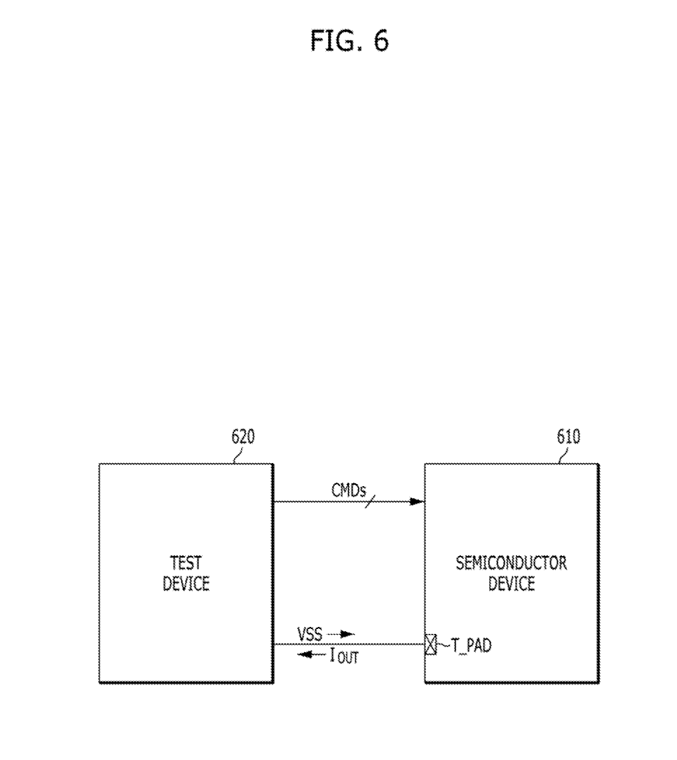

FIG. 6 is a diagram illustrating a semiconductor system according to an embodiment.

Referring to FIG. 6, the semiconductor system may include a semiconductor device 610 and a test device 620.

The semiconductor device 610 may include one or more through electrodes and may be one of semiconductor devices in FIGS. 2A, 2B and 5. The test device 620 may control various test operations of the semiconductor device 610.

The test device 620 may apply test commands CMDs to the semiconductor device 610 to accomplish a test operation to detect a crack in an insulating layer thereof. When the test commands CMDs are applied, the semiconductor device 610 may enable a test mode signal TM (of FIGS. 2A, 2B and 5) and may apply a power supply voltage to a through electrode. The test operation of the semiconductor device 610 is the same as described above in FIGS. 2A, 2B to 5.

The test device 620 may apply the test commands CMDs to the semiconductor device 610 and a source voltage VSS to a test pad T_PAD of the semiconductor device 610. In addition, the test device 620 may receive a current I_{OUT} outputted from the semiconductor device 610 in the test operation, and detect whether a crack is present in an insulating layer by using an amount of the current I_{OUT}.

In FIGS. 2A, 2B and 5, it is described and shown that a through electrode and the neighboring structure have the same operation as an NMOS transistor. However, when through electrodes 202, 502a and 502b and the neighboring structures 201, 203, 204, 501, 503a, 503b, 504a and 504b have the same operation as a PMOS transistor, the above test method may be used as well. In this case, a semiconductor device may include semiconductor substrates 201, 501 doped with an N-type impurity and active areas 204, 504a and 504b doped with a P-type impurity. In this semiconductor device, a source voltage is applied to through electrodes 202, 502a and 502b, and a power supply voltage is applied to active areas 204, 504a and 504b, and therefore it may be detected whether a crack is present in insulating layers 203, 503a and 503b by using a current flowing between the through electrodes 202, 502a and 502b and the active areas 204, 504a and 504b.

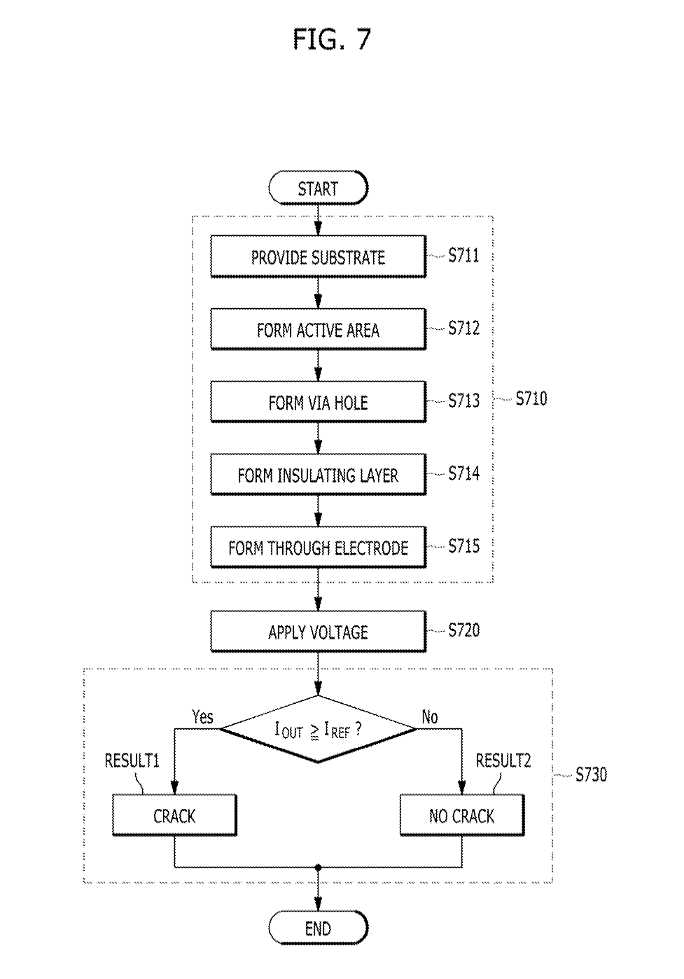

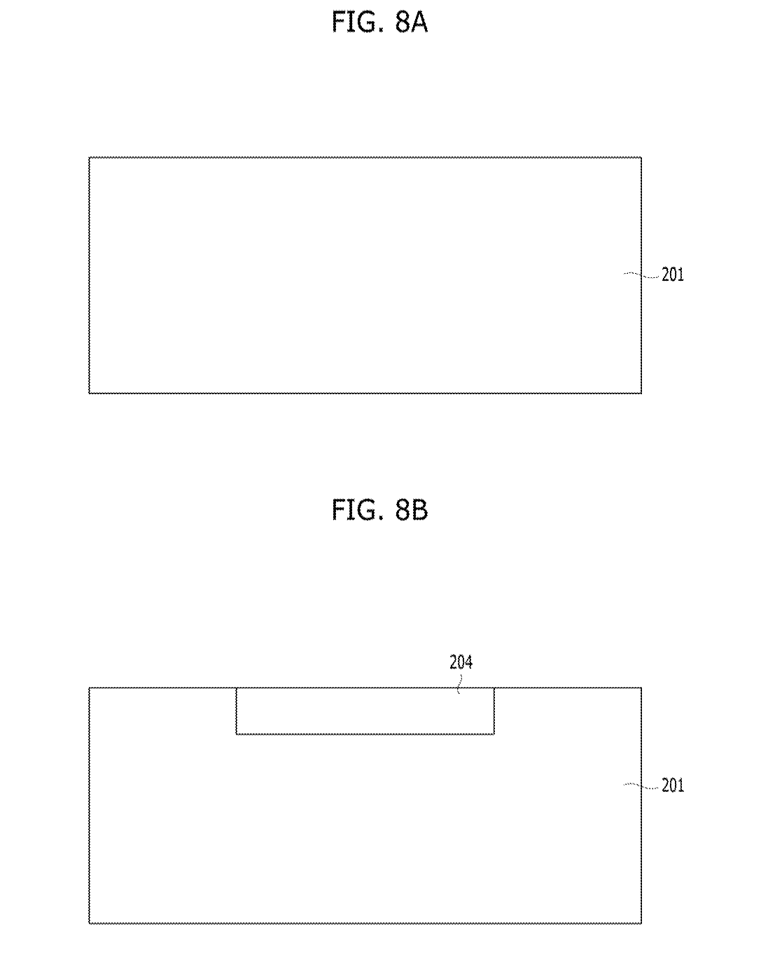

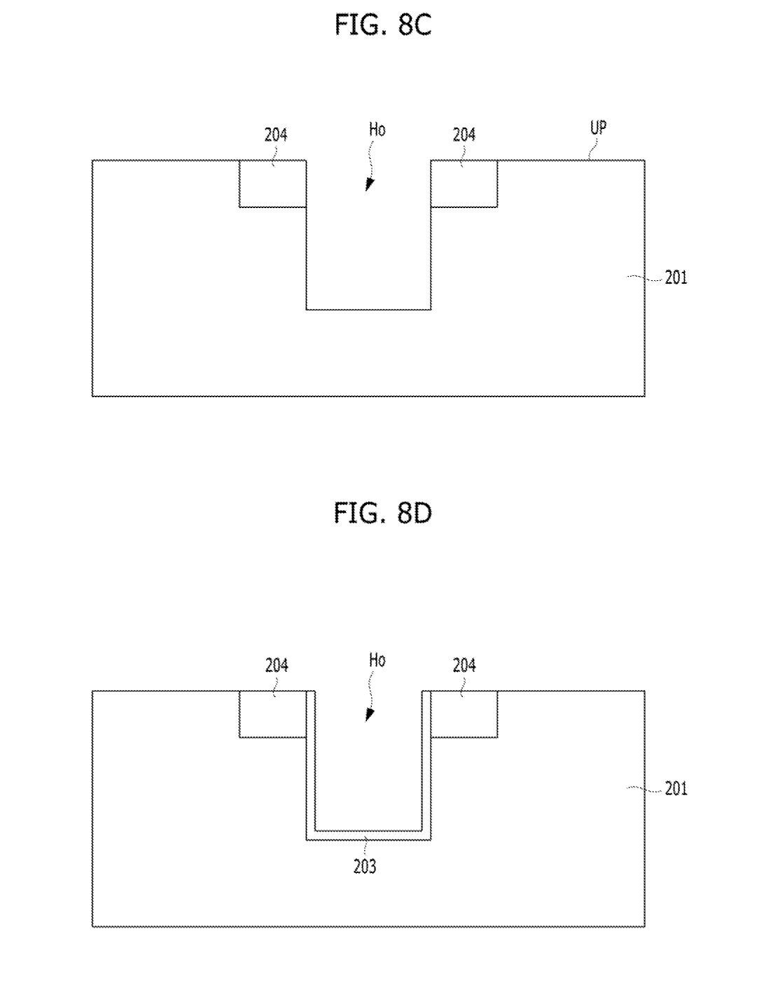

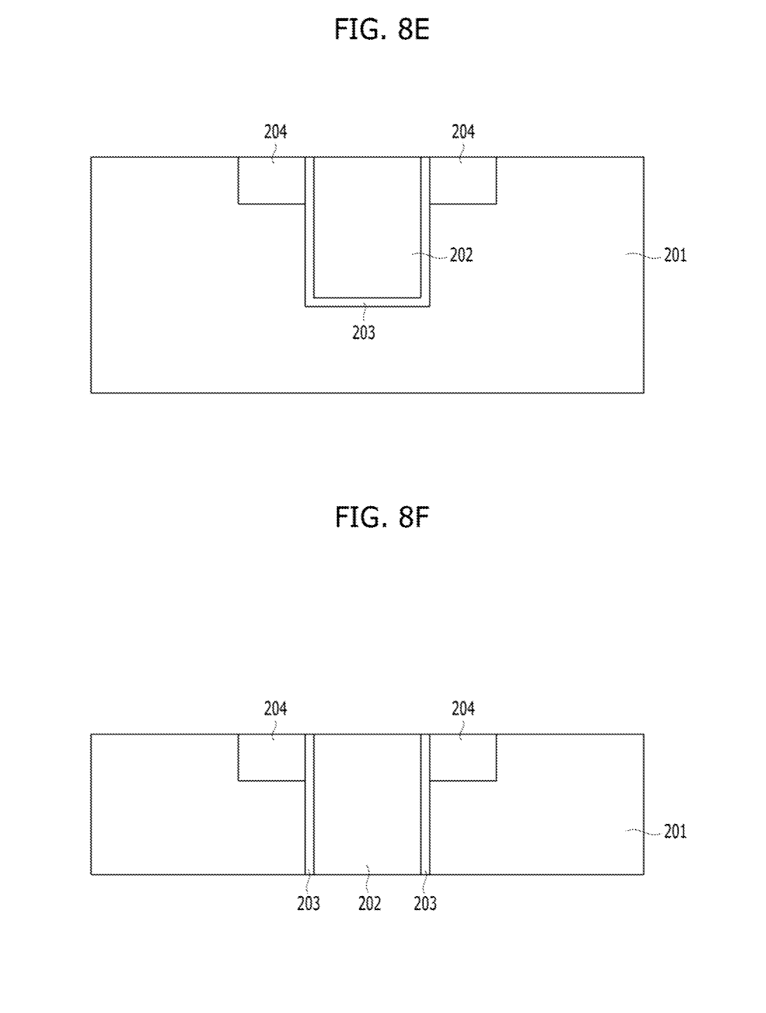

FIG. 7 is a flowchart illustrating a method of testing a semiconductor device according to an embodiment. FIGS. 8A to 8F are cross sectional views illustrating the method of FIG. 7. In FIGS. 2A and 2B, and FIGS. 8A to 8F, the same reference numerals or the same reference designators denote the same elements. For reference, the same method as illustrated in FIGS. 7 to 8F may be applied to the semiconductor device of FIG. 5.

Referring to FIG. 7, the method of testing the semiconductor device may include providing a semiconductor device at step S710, applying a voltage at step S720 and detecting a current lour at step S730.

At step 710, the semiconductor device in FIGS. 2A and 2B is fabricated. It may include steps of providing a semiconductor substrate 201 at step S711 corresponding to FIG. 8A, forming an active area 204 at step S712 corresponding to FIG. 8B, forming a via hole Ho at step S713 corresponding to FIG. 8C, forming an insulating layer 203 at step S714 corresponding to FIG. 8D, and forming a through electrode 202 at step S715 corresponding to FIG. 8E.

Referring to FIG. 8A, at step S711, the semiconductor substrate 201 doped with a first type impurity may be provided.

Referring to FIG. 8B, at step S712, the active area 204 may be formed by doping a second type impurity in the semiconductor substrate 201.

Referring to FIG. 8C, at step S713, the via hole Ho may be formed by penetrating the active area 204 and etching the semiconductor substrate 201 from the first side UP of the semiconductor substrate 201 to a direction perpendicular to a major axis of the semiconductor substrate 201. The via hole Ho may have a circle shape, an eclipse shape, a square shape, a diamond shape or a rhomboid shape, or a hexagonal shape, which is the same as the through electrode 202 to be formed subsequently, in a cross sectional view parallel to the first side UP of the semiconductor substrate 201.

The via hole Ho may partially penetrate the semiconductor substrate 201 in a direction perpendicular to a major axis of the semiconductor substrate 201 or entirely penetrate the semiconductor substrate 201 to a lower surface from an upper surface of the semiconductor substrate 201. The via hole Ho may be formed by dry etching using a plasma or by wet etching.

Referring to FIG. 8D, at step S714, the insulating layer 203 is formed along an inner wall of the semiconductor substrate 201, which is exposed by the via hole Ho. The insulating layer may be formed by a thermal oxidation process or a thin film deposition process such as chemical vapor deposition, plasma enhanced deposition, and atomic layer deposition.

Referring to FIG. 8E, at step S715, a conductive layer (not shown) is formed on the insulating layer 203 to fill in the via hole Ho. The conductive layer may include a doped polysilicon; tungsten, aluminum, copper, gold, silver, tantalum, titanium, molybdenum, cobalt, nickel, platinum and palladium; an alloy thereof; a conductive nitride thereof; a conductive metal oxide thereof, or a silicon alloy thereof. However, these are only examples, and a carbon electrode or other conductive materials to reduce the threshold voltage may be included. The conductive layer may be formed by a chemical vapor deposition, a physical vapor deposition, an electroless plating, an electroplating, or a combination thereof. Next, a planarization process is accomplished by removing the conductive layer until the upper surface of the semiconductor substrate 201 is exposed. As a result, as shown in FIG. 8E, the through electrode 202 buried in the via hole Ho may be formed. A planarization process may be accomplished by chemical-mechanical polishing or an etch back process.

After the semiconductor device is provided, at step S720, a first voltage may be applied to the through electrode 202, and a second voltage may be applied to the active area 204.

At step S730, it may be detected whether a crack is present in the insulating layer 203 by using the current I_{OUT} outputted through a test pad 206. When the current I_{OUT} is greater than or equal to a reference current, it is determined that a crack is present in the insulating layer 203 at step RESULT 1. When the current I_{OUT} is smaller than the reference current, it is determined no crack is present in the insulating layer 203 at step RESULT 2.

Additionally, referring to FIG. 8F, after a process step as shown in FIG. 8E is completed, when there is no crack in the insulating layer 203, it is possible that a through electrode structure is made by recessing an opposite side of the first side UP of the semiconductor substrate 201 in subsequent steps and by exposing a bottom surface of the through electrode 202.

Although various embodiments have been described for illustrative purposes, it will be apparent to those skilled in the art that various changes and modifications may be made without departing from the spirit and scope of the disclosure as defined in the following claims.

What is claimed is:

1. A semiconductor device comprising:
a semiconductor substrate doped with a first type impurity;
a through electrode inserted in the semiconductor substrate;
an active area formed in the semiconductor substrate to surround an upper portion of sidewalls of the through electrode, and doped with a second type impurity;
an insulating layer formed between the semiconductor substrate and the through electrode, and between the active area and the through electrode;
a drive circuit suitable for applying a first voltage to the through electrode in a test operation; and
a test pad connected to the active area, to which a voltage is applied during the test operation.

2. The semiconductor device according to claim 1, wherein a second voltage is applied to the test pad in the test operation.

3. The semiconductor device according to claim 2, wherein a current flowing between the through electrode and the active area is outputted to the outside through the test pad.

4. The semiconductor device according to claim 3, wherein the current outputted to the outside through the test pad is greater than or equal to a reference current when a crack exists in the insulating layer, and the current outputted to the outside through the test pad is smaller than the reference current when the crack does not exist in the insulating layer.

5. The semiconductor device according to claim 2, wherein the first type impurity is a P-type impurity, the second type impurity is an N-type impurity, the first voltage is a power supply voltage, and the second voltage is a source voltage lower than the power supply voltage.

6. The semiconductor device according to claim 2, wherein the first type impurity is an N-type impurity, the second type impurity is a P-type impurity, the first voltage is a source voltage, and the second voltage is a power supply voltage greater than the source voltage.

7. A semiconductor device comprising:
a semiconductor substrate doped with a first type impurity;
a plurality of through electrodes inserted in the semiconductor substrate;
a plurality of active areas formed in the semiconductor substrate, each surrounding an upper portion of sidewalls of the respective through electrodes, doped with a second type impurity;
a plurality of insulating layers, each formed between the semiconductor substrate and the respective through electrodes, and between the semiconductor substrate and the respective active areas;
one or more signal receiving circuits suitable for receiving a signal transmitted through a corresponding one of the plurality of through electrodes;
one or more signal transmitting and receiving circuits suitable for receiving a signal transmitted through a corresponding one of the plurality of through electrodes and transmitting a signal to be outputted through the corresponding through electrode; and
a plurality of test pads electrically connected to the plurality of active areas in a test operation, to which a voltage is applied,
wherein the one or more signal receiving circuit and the one or more signal transmitting and receiving circuit apply a first voltage to the respective through electrodes in the test operation.

8. The semiconductor device according to claim 7, wherein a second voltage is applied to the test pads in the test operation.

9. The semiconductor device according to claim 8, wherein a current flowing between the through electrode and the active area is outputted through the test pad.

10. The semiconductor device according to claim 9, wherein the current outputted through the test pad is greater than or equal to a reference current when a crack exists in the insulating layer, and the current outputted through the test pad is smaller than the reference current when the crack does not exist in the insulating layer.

11. The semiconductor device according to claim 8, wherein the first type impurity is a P-type impurity, the second type impurity is an N-type impurity, the first voltage is a power supply voltage, and the second voltage is a source voltage lower than the power supply voltage.

12. The semiconductor device according to claim 8, wherein the first type impurity is an N-type impurity, the second type impurity is a P-type impurity, the first voltage is a source voltage, and the second voltage is a power supply voltage greater than the source voltage.

13. The semiconductor device according to claim 7, wherein the signal receiving circuit receives a command signal or an address signal inputted to the semiconductor device through the corresponding through electrode, and the signal transmitting and receiving circuit transmits data to be outputted through the corresponding through electrode or receives data inputted to the semiconductor device through the corresponding through electrode.

14. A semiconductor system comprising:
a semiconductor substrate doped with a first type impurity,
a through electrode inserted in the semiconductor substrate,
an active area formed in the semiconductor substrate to surround an upper portion of sidewalls of the through electrode, and doped with a second type impurity,
an insulating layer formed between the semiconductor substrate and the through electrode, and between the semiconductor substrate and the active area, and
a test pad connected to the active area electrically in a test operation,
wherein a first voltage is applied to the through electrode in the test operation; and
a test device suitable for applying a second voltage to the test pad in the test operation, and detecting whether a crack exists in the insulating layer by using current outputted through the test pad.

15. The semiconductor system according to claim 14, wherein the test device determines that the insulating layer is satisfactory (or has no crack) when the current outputted through the test pad is smaller than a reference current in the test operation, and that the crack exists in the insulating layer when the current outputted through the test pad is greater than or equal to the reference current in the test operation.

16. The semiconductor system according to claim 14, wherein the first type impurity is a P-type impurity, the second type impurity is an N-type impurity, the first voltage is a power supply voltage, and the second voltage is a source voltage lower than the power supply voltage.

17. The semiconductor system according to claim 14, wherein the first type impurity is an N-type impurity, the second type impurity is a P-type impurity, the first voltage is a source voltage, and the second voltage is a power supply voltage greater than the source voltage.

18. A method of testing a semiconductor device, the method comprising:
providing a semiconductor substrate doped with a first type impurity;
forming an active area by doping a second type impurity in the semiconductor substrate;
forming a via hole by penetrating the active area and etching the semiconductor substrate from one side of the semiconductor substrate to a direction perpendicular to a major axis of the semiconductor substrate;
forming an insulating layer along an inner wall of the semiconductor substrate, the inner wall being exposed by the via hole;
forming a through electrode over the insulating layer to fill the via hole;
applying a first voltage to the through electrode and a second voltage to the active area; and
detecting current flowing between the through electrode and the active area.

19. The method according to claim 18, wherein the detecting the current further comprises:
outputting the current flowing between the through electrode and the active area to outside of the semiconductor device; and
comparing the outputted current with a reference current.

20. The method according to claim 19, wherein it is determined that a crack exists in the insulating layer when the outputted current is greater than or equal to the reference current, and that the crack does not exist in the insulating layer when the outputted current is smaller than the reference current.

21. The method according to claim 18, wherein the first type impurity is a P-type impurity, the second type impurity is an N-type impurity, the first voltage is a power supply voltage, and the second voltage is a source voltage lower than the power supply voltage.

22. The method according to claim 18, wherein the first type impurity is an N-type impurity, the second type impurity is a P-type impurity, the first voltage is a source voltage, and the second voltage is a power supply voltage greater than the source voltage.
